(19) United States
(12) Patent Application Publication
(10) Pub. No.: US 2016/0049370 A1
(43) Pub. Date: Feb. 18, 2016

(54) METHODS OF FORMING MIS CONTACT STRUCTURES FOR SEMICONDUCTOR DEVICES BY SELECTIVE DEPOSITION OF INSULATING MATERIAL AND THE RESULTING DEVICES

(71) Applicant: GLOBALFOUNDRIES Inc., Grand Cayman (KY)

(72) Inventors: Vimal Kamineni, Mechanicville, NY (US); Xiuyu Cai, Niskayuna, NY (US); Xunyuan Zhang, Albany, NY (US)

(21) Appl. No.: 14/457,370

(22) Filed: Aug. 12, 2014

(51) Int. Cl. H01L 23/535; H01L 21/768; H01L 23/532

(52) U.S. Cl. CPC H01L 23/535; H01L 23/5329; H01L 21/76879; H01L 21/76831

(57) ABSTRACT

One method disclosed herein includes, among other things, forming at least one layer of insulating material above a semiconductor layer, performing at least one contact opening etching process to form a contact opening in the at least one layer of insulating material that exposes a portion of the semiconductor layer, selectively depositing a metal-oxide insulating material through the contact opening on the exposed surface of the semiconductor layer, and forming a conductive contact in the contact opening that contacts the metal-oxide insulating material.

### BACKGROUND OF THE INVENTION

1. Field of the Invention

The present disclosure generally relates to the fabrication of integrated circuits, and, more particularly, to various methods of forming MIS (Metal-Insulator-Semiconductor) contact structures for semiconductor devices by selective deposition of insulating material and the resulting semiconductor devices.

2. Description of the Related Art

In modern integrated circuits, such as microprocessors, storage devices and the like, a very large number of circuit elements, especially transistors, are provided and operated on a restricted chip area. Transistors come in a variety of shapes and forms, e.g., planar transistors, FinFET transistors, nanowire devices, etc. Irrespective of the physical configuration of the transistor device, each device comprises drain and source regions and a gate electrode structure positioned above and between the source/drain regions. Upon application of an appropriate control voltage to the gate electrode, a conductive channel region forms between the drain region and the source region.

Irrespective of whether a planar or non-planar device is considered, electrical connections must be formed to the device so that it may operate as intended. That is, electrical connections must be made to the source region, the drain region and the gate electrode of the device. Typically, the conductive structures that actually make contact with the device itself, i.e., the source region, the drain region and the gate electrode, are referred to as “contacts” within the industry. Such conductive contacts are formed in one or more layers of insulating material. The entire arrangement of the conductive contacts and the associated layer(s) of insulating material are sometimes referred to as the “contact level” of the overall electrical “wiring arrangement” that is formed to provide electrical connection to the integrated circuit device.

The ongoing decrease in device dimensions also mandated an associated decrease in physical size of the contact openings (and contacts) that are formed to establish electrical connections to, for example, the source/drain regions. That is, there is very little room in the contact openings for all of the layers of material that are needed when forming conductive contact structures. Device designers have explored using different contact methods and structures to improve the operational characteristics of the devices and/or to simplify processing techniques. For example, U.S. Pat. No. 8,110,887 is an example of an MIS (Metal-Insulator-Semiconductor) contact structure for silicon-based transistor devices.

FIGS. 1A-1E depict one illustrative prior art technique for forming MIS contact structures for semiconductor devices. FIG. 1A is a simplified view of the illustrative prior art transistor device 10 at an early stage of manufacturing. The device 10 is formed in an active region of a semiconductor substrate 12 that is defined by a simplistically depicted trench isolation region 14. The device 10 also includes a schematically depicted gate structure 16, a gate cap layer 18 (e.g., silicon nitride), sidewall spacers 20, source/drain regions 22, a thin native oxide layer 13 (that is formed when the source/drain regions are exposed to air, and it may or may not be present in all situations) and an illustrative layer of insulating material 24. Although the layer of insulating material 24 is simplistically depicted as being a single layer of material, in practice, the layer of insulating material 24 may be comprised of a plurality of layers of insulating material, perhaps with an intervening etch stop layer formed between such layers of material.

FIG. 1B depicts the device 10 after one or more etching processes were performed through a patterned etch mask (not shown), such as a patterned layer of photoresist or a patterned hard mask layer, to define illustrative contact openings or trenches 26 in the layer of insulating material 24. The formation of the contact openings 26 normally exposes a portion of the source/drain regions 22. However, as depicted in FIG. 1C, as part of the MIS contact formation process, a pre-clean process will be performed to remove any residual insulating materials, including the exposed portions of the native oxide layer 13 (when present) to insure that the upper surface of the source/drain regions 22 are exposed. FIG. 1D depicts the device 10 after a layer of contact insulating material 28 (for the MIS contact) and a conductive material layer 30 were sequentially formed in the contact openings 26. In one illustrative embodiment, the layers 28, 30 may be formed by performing a conformal atomic layer deposition (ALD), chemical vapor deposition (CVD) or physical vapor deposition (PVD) process. The layer of contact insulating material 28 may be comprised of a variety of different materials, e.g., silicon nitride, a high-k insulating material (k value of 10 or greater), such as TiO₂, La₂O₃, Al₂O₃, HfO₂, etc., silicon oxynitride, etc., and it may be formed to any desired thickness, e.g., 0.5-2 nm. The conductive material layer 30 may be comprised of a variety of different metals or metal compounds, e.g., Ti, W, Mo, Co, TiN, Al, etc. FIG. 1E depicts the device after one or more chemical mechanical polishing (CMP) operations were performed to remove the excess amounts of the layer of contact insulating material 28 and the conductive material layer 30 positioned outside of the contact openings 26. These operations result in the formation of the MIS contact structures 32 depicted in FIG. 1E wherein the conductive material layer 30, the layer of contact insulating material 28 and the source/drain region 22 provide the basic metal-insulator-semiconductor structure for the MIS contact structures 32.

The formation of such MIS contact structures 32 presents several challenges. In general, the overall resistance of the contact structure 32 (R_{C}) is the sum of two resistances arranged in series: the tunneling resistance through the layer of insulating material 28 (R_{T}) plus the resistance associated with an effective Schottky barrier height (R_{SB}). However, these resistance values (R_{T} and R_{SB}) are inversely dependent upon the thickness of the layer of contact insulating material 28. Thus, minimizing the overall contact resistance (R_{C}) of the MIS contact structure 32 involves a “trade-off” between the two resistance values (R_{T} and R_{SB}). Furthermore, dipoles at the metal and insulator interface, due to the insertion of the layer of insulating material, will effectively shift the metal work function of the conductive layer 30 relative to the semiconductor material, i.e., the substrate 12. In addition, the choice of the insulator is critical to have a low conduction band offset for electrons and low valence band offset for holes between the insulator and semiconductor. Controlling the thickness of the layer of contact insulating material 28 is very important to optimize the trade-off of Schottky barrier height and tunneling resistance. Another issue that needs to be addressed is the very small size of the contact openings 26. In general, as device dimensions continue to shrink, the physical size of the openings, i.e., the critical dimension of the contact openings 26 in a gate-length direction of the device 10, becomes so small that it is difficult to fit all of the desired conductive materials into the contact openings 26.

What is needed for modern, high packing density applications is an MIS contact structure that is more efficient and effective in terms of its use of space and the formation of a lower resistance structure. The present disclosure is directed to various methods of forming MIS contact structures for semiconductor devices by selective deposition of insulating material and the resulting semiconductor devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming MIS contact structures for semiconductor devices by selective deposition of insulating material and the resulting semiconductor devices. One method disclosed herein includes, among other things, forming at least one layer of insulating material above a semiconductor layer, performing at least one contact opening etching process to form a contact opening in the at least one layer of insulating material that exposes a portion of the semiconductor layer, selectively depositing a metal-oxide insulating material through the contact opening on the exposed surface of the semiconductor layer, and forming a conductive contact in the contact opening that contacts the metal-oxide insulating material.

Another illustrative method disclosed herein includes, among other things, forming at least one layer of insulating material above a semiconductor layer, performing at least one contact opening etching process to form a contact opening in the at least one layer of insulating material that exposes a portion of the semiconductor layer, wherein the contact opening has sidewalls, selectively depositing a metal-oxide insulating material through the contact opening on the exposed surface of the semiconductor layer without forming the metal-oxide insulating material on the sidewalls of the contact opening, wherein the metal-oxide insulating material has a k value of 10 or greater, and forming a conductive contact in the contact opening that contacts the metal-oxide insulating material.

One illustrative device disclosed herein includes, among other things, a layer of semiconductor material, a layer of insulating material having a contact opening formed therein positioned above the layer of semiconductor material, wherein the contact opening has sidewalls defined by the layer of insulating material, a metal-oxide insulating material positioned on and in physical contact with the semiconductor layer, and a conductive contact structure positioned in the contact opening, wherein the conductive contact structure is positioned on and in physical contact with an upper surface of the metal-oxide insulating material and on and in physical contact with the insulating material that defines the sidewalls of the contact opening.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1E depict one illustrative prior art technique for forming MIS contact structures for semiconductor devices; and

FIGS. 2A-2F depict various illustrative methods disclosed herein for forming MIS contact structures by selective deposition of insulating material and the resulting semiconductor devices.

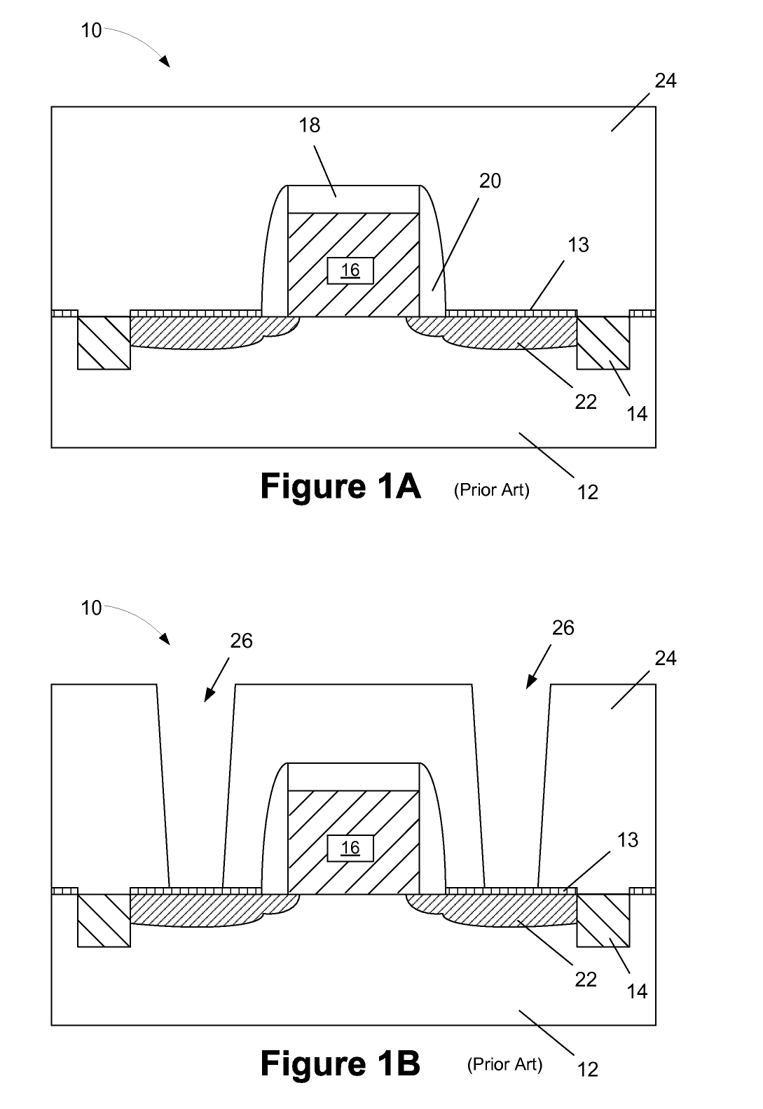

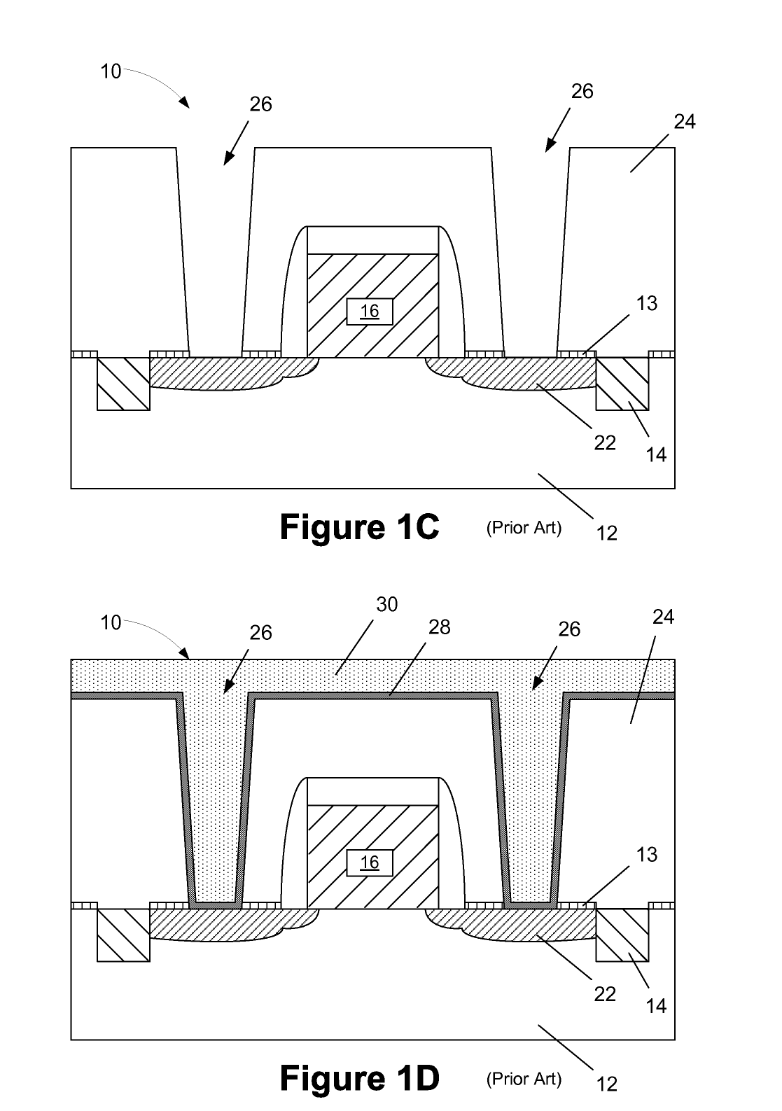

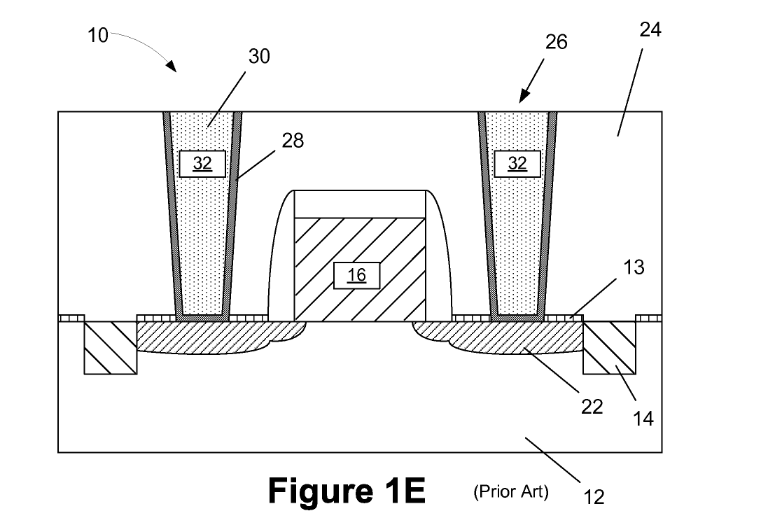

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally relates to various methods of forming MIS contact structures for semiconductor devices by selective deposition of insulating material and the resulting semiconductor devices. Moreover, as will be readily apparent to those skilled in the art upon a complete reading of the present application, the present method is applicable to a variety of devices, including, but not limited to, logic devices, memory devices, etc., and the methods disclosed herein may be employed to form N-type or P-type semiconductor devices. The methods and devices disclosed herein may be employed in manufacturing products using a variety of technologies, e.g., NMOS, PMOS, CMOS, etc., and they may be employed in manufacturing a variety of different devices, e.g., memory devices, logic devices, ASICs, etc.

As will be appreciated by those skilled in the art after a complete reading of the present application, the inventions disclosed herein may be employed in forming integrated circuit products using planar transistor devices, as well as so-called 3D devices, such as FinFETs, nanowire devices, etc. For purposes of disclosure, reference will be made to an illustrative process flow wherein an illustrative planar transistor device is formed. However, the inventions disclosed herein should not be considered to be limited to such an illustrative example. With reference to the attached figures, various illustrative embodiments of the methods and devices disclosed herein will now be described in more detail. The gate structure for the device may be formed using either so-called “gate-first” or “replacement gate” (“gate-last” or “gate-metal-last”) techniques. Unless otherwise noted, the various components and structures of the device 100 disclosed herein may be formed using a variety of different materials and by performing a variety of known techniques, e.g., a chemical vapor deposition (CVD) process, an atomic layer deposition (ALD) process, a thermal growth process, spin-coating techniques, etc. The thicknesses of these various layers of material may also vary depending upon the particular application.

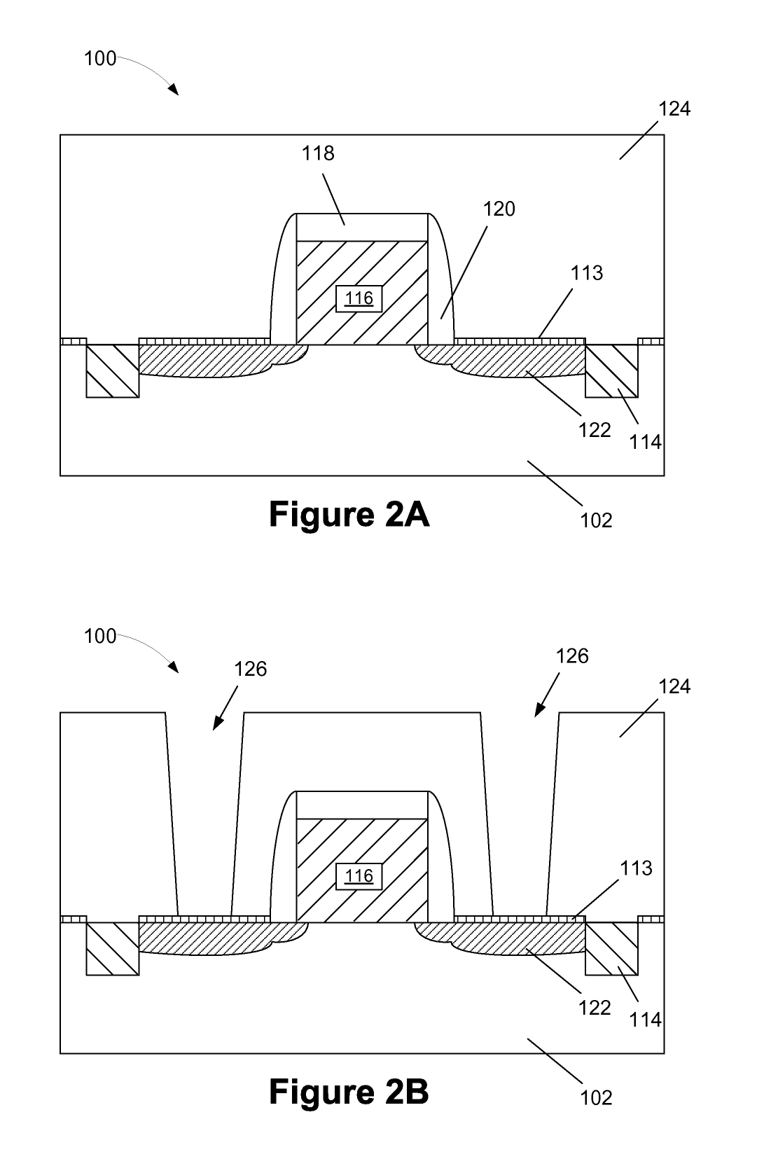

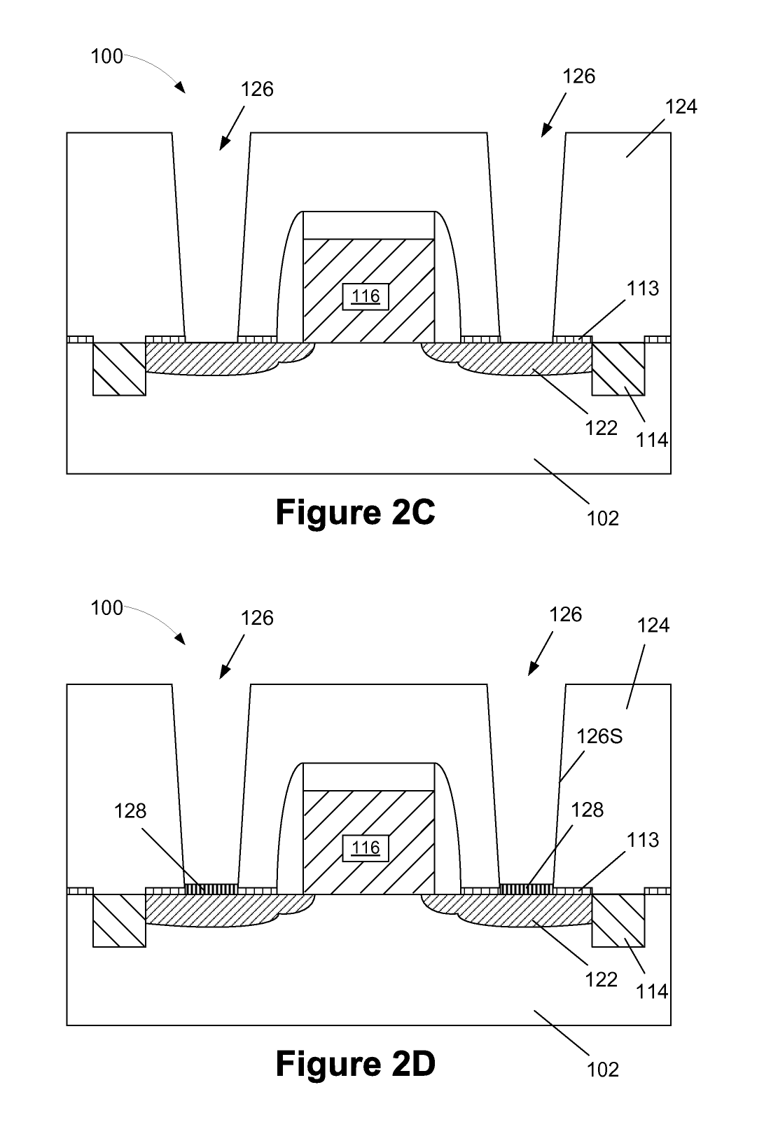

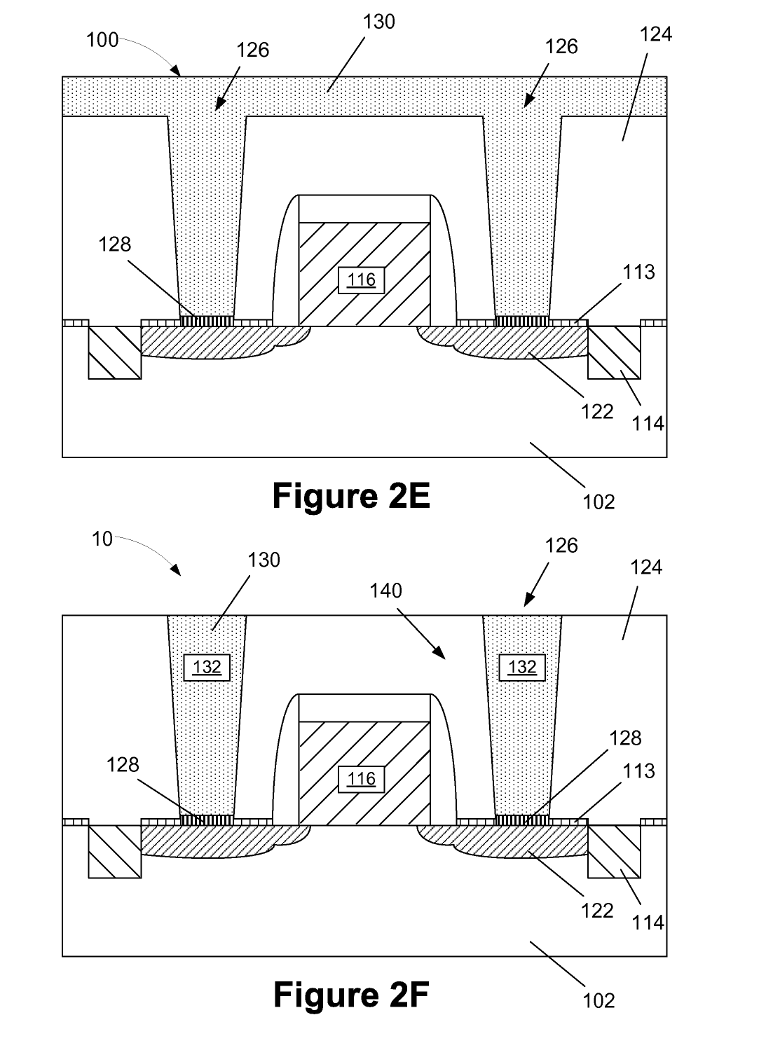

FIG. 2A is a simplified view of the illustrative transistor device 100 at an early stage of manufacturing. The device 100 is formed in an active region of a semiconductor substrate 102 that is defined by a simplistically depicted trench isolation region 114. The substrate 102 may have a variety of configurations, such as the depicted bulk silicon configuration. The substrate 102 may also have a silicon-on-insulator (SOI) configuration that includes a bulk silicon layer, a buried insulation layer and an active layer, wherein semiconductor devices are formed in and above the active layer. The substrate 102 may be made of silicon or it may be made of materials other than silicon. Thus, the terms “substrate” or “semiconductor substrate” should be understood to cover all semiconducting materials and all forms of such materials.

With continuing reference to FIG. 2A, the device 100 also includes a schematically depicted gate structure 116, a gate cap layer 118 (e.g., silicon nitride), sidewall spacers 120, source/drain regions 122, a native oxide layer 113 and an illustrative layer of insulating material 124. Although the layer of insulating material 124 is simplistically depicted as being a single layer of material, in practice, the layer of insulating material 124 may be comprised of a plurality of layers of insulating material, perhaps with an intervening etch stop layer formed between such layers of material. Additionally, various doped regions, e.g., halo implant regions, well regions and the like, are also not depicted in the attached drawings. A thin silicon nitride contact etch stop layer (not shown) may also be formed on the device prior to the formation of the layer of insulating material 124. The gate structure 116 is representative in nature of any type of gate structure used in manufacturing semiconductor devices. The gate structure 116 may be manufactured using gate-first or replacement gate techniques.

FIG. 2B depicts the device 100 after one or more etching processes were performed through a patterned etch mask (not shown), such as a patterned layer of photoresist or a patterned hard mask layer, to define illustrative contact openings or trenches 126 in the layer of insulating material 124. The size and shape of the contact openings may vary depending upon the particular application. For example, the contact openings 126 may be discreet point-type contacts having a square or circular configuration or they may be line-type features that span the entire active region in the source/drain regions 122 of the device 10. In current day devices, the width of the contact openings 126 (in the gate length direction of the device 100) may be as small as about 10-30 nm, and further reductions in size are expected in future generation devices. The formation of the contact openings 126 normally exposes a portion of the source/drain regions 122. FIG. 2B depicts the situation where the native oxide layer 113 is still present (it may be formed before or after the formation of the contact openings 126. However, as depicted in FIG. 2C, as part of the MIS contact formation process, a pre-clean process will be performed to remove any residual insulating materials, including the exposed portions of the native oxide layer 113 (when present) to insure that the upper surface of the source/drain regions 122 are exposed. Of course, as will be appreciated by those skilled in the art after a complete reading of the present application, the methods disclosed herein may be employed when forming traditional contact structures as well as when forming so-called self-aligned contacts, wherein the conductive contact structure lands on the gate cap layer as well as the sidewall spacer.

FIG. 2D depicts the device 10 after a selective deposition process is performed to selectively form a metal-oxide insulating material 128 on the exposed portions of the source/drain regions 122. This approach introduces a simple self-assembly-monolayer (SAM) formation which will prevent the insulating layer growing on the sidewall of the trenches. The selectively-deposited metal-oxide insulating material 128 may be comprised of a variety of different metal-oxide materials, including, but not limited to, a high-k insulating material (k value of 10 or greater), such as TiO₂, La₂O₃, Al₂O₃, HfO₂, etc. However, the metal-oxide insulating material 128 need not be a high-k material. The selectively-deposited metal-oxide insulating material 128 may also be formed to any desired thickness, e.g., 1-2 nm. In one illustrative embodiment, the selectively-deposited metal-oxide insulating material 128 may be formed by performing the metal-oxide CVD process described in Kang et. al., “Selective Deposition of Hafnium Oxide Nanothin Films on OTS Patterned Si(100) Substrates by Metal-Organic Chemical Vapor Deposition,” IEEE Transactions on Nanotechnology, Vol. 5, No. 6, November 2006, which is hereby incorporated by reference in its entirety. In one embodiment where the selectively-deposited metal-oxide insulating material 128 is made of hafnium oxide, the selective deposition method may be performed by using a combination of μCP using octadecyltrichlorosiliane (OTS) and metal-organic chemical vapor deposition (MOCVD), wherein the process may be performed at a temperature of between 150-400° C. and at a pressure of 3×10⁻² Torr. Note that, using the novel process flow described herein, the selectively-deposited metal-oxide insulating material 128 does not deposit on the sidewalls 126S of the contact openings 126. Accordingly, there is more room within the contact openings 126 for the conductive materials that will subsequently be formed in the contact openings 126. That is, by forming the selectively-deposited metal-oxide insulating material 128 only on the substrate, the aspect ratio of the contact openings 126 is effectively decreased, thereby making filling of the contact openings 126 with conductive material relatively easier.

FIG. 2E depicts the device 100 after one or more conductive material layers 130 (schematically depicted as a single layer of conductive material) are formed in the contact openings 126 and on the selectively-deposited metal-oxide insulating material 128. Note that the conductive material layer 130 sets the correct work function to lower the contact resistance for a good MIS contact. In one illustrative embodiment, the conductive material layer 130 may be formed by performing an ALD or PVD process. The conductive material layer 130 may be comprised of a variety of different materials, e.g., a metal, a metal alloy, polysilicon, etc., and it may be formed to any desired thickness, and it is typically formed so as to overfill the contact openings 126. One or more barrier layers (not depicted) may be formed in the contact openings as part of the conductive material layer 130, e.g., the formation of a titanium nitride liner, followed by overfilling the contact openings 126 with a conductive material, such as tungsten. The conductive material layer 130, the selectively-deposited metal-oxide insulating material 128 and the source/drain region 122 provide the basic metal-insulator-semiconductor contact structure for the MIS contacts disclosed herein.

FIG. 2F depicts the device 100 after a CMP process was performed to planarize the upper surface of the layer of insulating material 124, which results in the removal of excess portions of the conductive material layer 130 and the formation of the contact structures 140. As will be appreciated by those skilled in the art, although the formation of MIS contact structures 140 to the source/drain regions 122 of the device 100 has been depicted herein, the methodologies disclosed herein may be employed in forming MIS contact structures to other device regions, such as forming an MIS contact to the gate structure 116 or a resistor, a component of a bipolar transistor, a photonic device, other power devices, etc.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

1. A method of forming an MIS contact structure, comprising:
forming at least one layer of insulating material above a semiconductor layer;
performing at least one contact opening etching process to form a contact opening in said at least one layer of insulating material that exposes a portion of said semiconductor layer;
selectively depositing a metal-oxide insulating material through said contact opening on the exposed surface of said semiconductor layer; and
forming a conductive contact in said contact opening that contacts said metal-oxide insulating material.

2. The method of claim 1, wherein said semiconductor layer comprises one of a source/drain region, a gate structure or a resistor.

3. The method of claim 1, wherein said metal-oxide insulating material has a k value of 10 or greater.

4. The method of claim 1, wherein said metal-oxide insulating material is one of TiO₂, La₂O₃, Al₂O₃ or HfO₂.

5. The method of claim 1, wherein said conductive contact is comprised of one of a metal, a metal alloy or polysilicon.

6. The method of claim 1, wherein said contact opening has sidewalls, and wherein said metal-oxide insulating material covers lower portions of said sidewalls of said contact opening and exposes upper portions of said sidewalls.

7. A method of forming an MIS contact structure, the method comprising:
forming at least one layer of insulating material above a semiconductor layer;
performing at least one contact opening etching process to form a contact opening in said at least one layer of insulating material that exposes a portion of said semiconductor layer, wherein said contact opening has sidewalls;
selectively depositing a substantially horizontally oriented insulating material layer through said contact opening on the exposed surface of said semiconductor layer, said substantially horizontally oriented insulating material layer exposing said sidewalls of said contact opening positioned above an upper surface of said substantially horizontally oriented insulating material layer, wherein said substantially horizontally oriented insulating material layer comprises a metal-oxide insulating material having a k value of 10 or greater; and
forming a conductive contact in said contact opening that contacts said substantially horizontally oriented insulating material layer.

8. The method of claim 7, wherein said semiconductor layer comprises one of a source/drain region, a gate structure or a resistor.

9. The method of claim 7, wherein said metal-oxide insulating material is one of TiO₂, La₂O₃, Al₂O₃ or HfO₂.

10. The method of claim 7, wherein said conductive contact is comprised of one of a metal, a metal alloy or polysilicon.

11.-15. (canceled)

16. The method of claim 1, wherein selectively depositing said metal-oxide insulating material through said contact opening on said exposed surface of said semiconductor layer comprises selectively depositing a substantially horizontally oriented layer of said metal-oxide insulating material on said exposed surface of said semiconductor material at a bottom of said contact opening, wherein said substantially horizontally oriented layer of said metal-oxide insulating material exposes sidewall surfaces of said contact opening positioned above an upper surface of said substantially horizontally oriented layer of metal-oxide insulating material.

17. The method of claim 1, wherein said selectively deposited metal-oxide insulating material consists of a substantially horizontally oriented material layer covering said exposed surface of said semiconductor material at a bottom of said contact opening, said substantially horizontally oriented material layer exposing sidewall surfaces of said contact opening positioned above an upper surface of said substantially horizontally oriented material layer.

18. A method of forming an MIS contact structure, the method comprising:
forming at least one layer of insulating material above a semiconductor layer;
performing a contact opening etching process to form a contact opening in said at least one layer of insulating material;
performing a pre-clean process through said contact opening to remove at least a native oxide layer formed above said semiconductor layer and expose a portion of said semiconductor layer at a bottom of said contact opening;
selectively depositing a layer of metal-oxide insulating material through said contact opening on said exposed surface of said semiconductor layer; and
forming a conductive contact in said contact opening that contacts said selectively deposited layer of metal-oxide insulating material.

19. The method of claim 18, wherein selectively depositing said metal-oxide insulating material through said contact opening on said exposed surface of said semiconductor layer comprises selectively depositing a substantially horizontally oriented layer of said metal-oxide insulating material on said exposed surface of said semiconductor material at a bottom of said contact opening, wherein said substantially horizontally oriented layer of said metal-oxide insulating material exposes sidewall surfaces of said contact opening positioned above an upper surface of said substantially horizontally oriented layer of metal-oxide insulating material.

20. The method of claim 18, wherein said selectively deposited metal-oxide insulating material consists of a substantially horizontally oriented material layer covering said exposed surface of said semiconductor material at a bottom of said contact opening, said substantially horizontally oriented material layer exposing sidewall surfaces of said contact opening positioned above an upper surface of said substantially horizontally oriented material layer.

21. The method of claim 18, wherein said selectively deposited metal-oxide insulating material covers lower sidewall surface portions of said contact opening and exposes upper sidewall surface portions of said contact opening.

22. The method of claim 18, wherein said semiconductor layer comprises one of a source/drain region, a gate structure or a resistor.

23. The method of claim 18, wherein said selectively deposited metal-oxide insulating material has a k value of 10 or greater.

24. The method of claim 18, wherein said selectively deposited metal-oxide insulating material is one of TiO₂, La₂O₃, Al₂O₃ or HfO₂.

25. The method of claim 18, wherein said conductive contact is comprised of one of a metal, a metal alloy or polysilicon.
